(19) United States
(12) Patent Application Publication
(10) Pub. No.: US 2012/0143558 A1
(43) Pub. Date: Jun. 7, 2012

(54) TEST APPARATUS FOR MULTI-CHIP PACKAGE AND TEST METHOD THEREOF

(75) Inventor: Jung Woong Yang, Yongin-si (KR)

(73) Assignees: DAWIN TECHNOLOGY INC., Seoul (KR); SAMSUNG ELECTRONICS CO., LTD., Suwon-si (KR)

(21) Appl. No.: 13/310,397

(22) Filed: Dec. 2, 2011

(30) Foreign Application Priority Data
Dec. 3, 2010 (KR) 10-2010-0122379

(51) Int. Cl. G06F 19/00; G01R 31/3183; G01R 31/3193; G01R 31/319

(52) U.S. Cl. 702/118

(57) ABSTRACT

A multi-chip package test apparatus is for testing a plurality of semiconductor packages including a plurality of flash memories and an application specific integrated circuit (ASIC) stacked on a single substrate. The multi-chip package test apparatus includes a plurality of test sockets configured to receive the plurality of semiconductor packages, respectively, a plurality of central processing units (CPUs) mounted on a test board and each configured to execute a package test of a respective one of the semiconductor packages received by the plurality of sockets, and a plurality of multiple access dynamic random access memory (DRAM) device operatively interposed between the CPUs and test sockets, respectively, each of the multiple access DRAM devices configured with separate memory areas for access by a respective CPU and a respective ASIC of the semiconductor packages.

### CROSS-REFERENCE TO RELATED APPLICATIONS

A claim of priority under 35 U.S.C. §119 has been made to Korean Patent Application No. 10-2010-0122379 filed Dec. 3, 2010, the entirety of which is incorporated by reference herein.

### BACKGROUND

The inventive concepts described herein relate to a multi-chip test device, and more particularly, relate to a multi-chip package test device capable of testing a multi-chip package with an Application Specific Integrated Circuit (ASIC) plus flash format using a Central Processing Unit (CPU) and a multiple access Dynamic Random Access Memory (DRAM) device mounted on a test board.

Advances in electronic engineering technology and semiconductor integrated technologies have lead to increased miniaturization and multi-functionality of electronic devices. For example, a handheld telephone terminal such as a cellular phone inevitably necessitates a mobile communication function as well as a multimedia playback function.

The miniaturization and multi-functionality of electronic devices can be implemented by system-on-chip (SOC) technology, in which a plurality of functions are integrated in one chip, and/or by multi-chip package (MCP) technology in which a plurality of semiconductor chips are packaged together as a single chip configuration.

A semiconductor package including memory devices, such as a flash memory, DRAM, and Static Random Access Memory (SRAM) are subjected to various quality tests such as a burn-in test, a humidity test, and so on. Generally, the semiconductor package is powered by an electrical signal from a mother board on which various electronic apparatuses are disposed.

Semiconductor package testing may include a reliability test, followed by board level testing. Reliability testing generally focuses on identifying defects (e.g., short-circuits) in the semiconductor package, and can including environmental testing, such as thermal testing and physical impact testing. On the other hand, board level testing is executed to determine whether the semiconductor package operates correctly when the package is mounted at a system level (e.g., on a system board.)

In the case of reliability testing, the semiconductor package may be mounted on a test board connected to a test apparatus. A socket mount type test board may be used as the test board.

FIG. 1 is a diagram illustrating a typical multi-chip package test apparatus.

Referring to FIG. 1, a multi-chip package test apparatus 100 includes a tester 110 having a CPU 111 and a DRAM 115, and a plurality of sockets 130 to 130n. A plurality of multi-chip packages 120 to 12n are inserted in the sockets 130 to 130n, respectively. Each of the multi-chip packages 120 to 120n includes a respective ASIC 121 to 12n and a respective flash memory 125 to 125n.

During a package test, the CPU 111 reads a test algorithm and tests functions on the ASICs 121 to 12n and the flash memories 125 to 125n in the multi-chip packages 120 to 120n using a test pattern. The DRAM 115 stores the test algorithm and test results of the ASICs 121 to 121n and the flash memories 125 to 125n, and is used as a main memory of the CPU 111.

### SUMMARY

In an embodiment of the inventive concept, a multi-chip package test apparatus is provided for testing a plurality of semiconductor packages including a plurality of flash memories and an application specific integrated circuit (ASIC) stacked on a single substrate. The multi-chip package test apparatus includes a plurality of test sockets configured to receive the plurality of semiconductor packages, respectively, a plurality of central processing units (CPUs) mounted on a test board and each configured to execute a package test of a respective one of the semiconductor packages received by the plurality of sockets; and a plurality of multiple access dynamic random access memory (DRAM) device operatively interposed between the CPUs and test sockets, respectively, each of the multiple access DRAM devices configured with separate memory areas for access by a respective CPU and a respective ASIC of the semiconductor packages.

In another example embodiment of the inventive concept, a multi-chip package test method is provided which include inserting multi-chip packages each formed of an application specific integrated circuit (ASIC) and a flash memory into respective test sockets, testing functions on the multi-chip packages inserted into the respective test sockets, the testing executed by respective central processing units (CPUs), storing test results in an ASIC access areas of respective multiple access dynamic random access memory (DRAM) devices, comparing the test results with a reference value, the comparing executed by the respective CPUs, and evaluating and storing a pass/fail status of each of the multi-chip packages.

In yet another embodiment of the inventive concept, a multi-chip package test apparatus is provided which includes a plurality of test sockets each configured to receive a package for testing, a plurality of multiple access dynamic access memory (DRAM) devices respectively connected to the plurality of test sockets by at least one first channel, and a plurality of central processing units (CPUs) respectively connected to the plurality of multiple access DRAM devices by at least one second channel.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a diagram illustrating a typical multi-chip package test apparatus;

FIG. 2 is a diagram illustrating a package solution in which packages are independently formed to have different package formats in a memory link architecture;

FIG. 3 is a diagram illustrating a multi-chip package test apparatus according to an embodiment of the inventive concept; and

FIG. 4 is a flowchart illustrating a multi-chip package test method according to an embodiment of the inventive concept.

### DETAILED DESCRIPTION

The inventive concept is described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

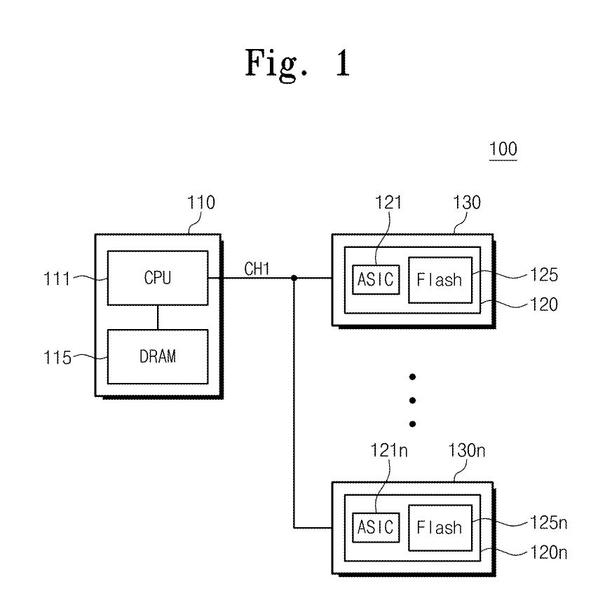

In the typical multi-chip package test apparatus 100 of previously described FIG. 1, the apparatus 100 tests functions on the ASICs 121 to 121n and the flash memories 125 to 125n in the multi-chip packages 120 to 120n using a single CPU 111 and a single DRAM 115. This however may however result in inefficient memory use and extended test time. That is, the CPU 111 and the DRAM 115 constituting the typical tester 110 are used to perform processes other than the package test, which can result inefficient memory use. Further, testing is performed sequentially with respect to the multi-chip packages 120 to 120n, which can result in a relatively long test period.

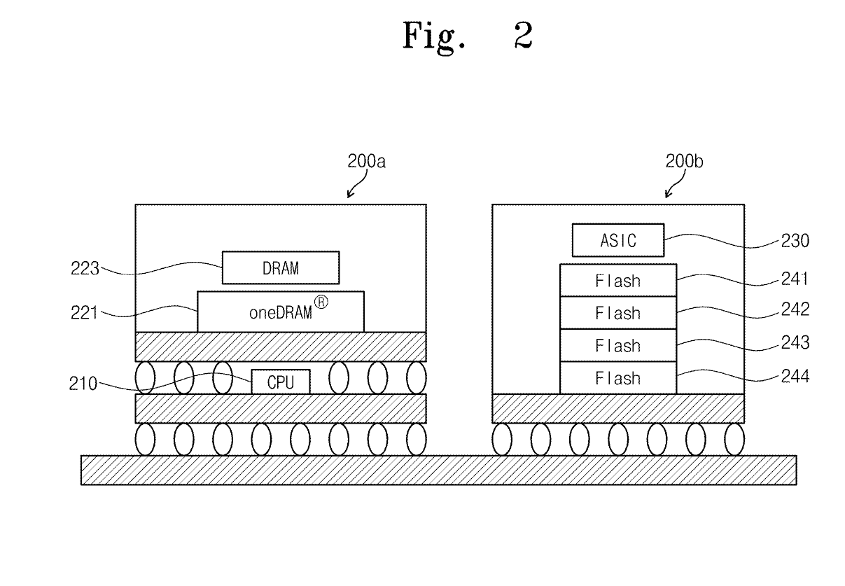

FIG. 2 is a diagram illustrating a package solution in which packages are independently formed of different package structures in a memory link architecture.

Referring to FIG. 2, the first package 200a has a package-on-package (POP) structure and the second package 200b has a multi-chip package (MCP) structure. That is, the first and second packages 200a and 200b are formed independently to of different package structures in a memory link architecture.

The memory link architecture includes one chip structure in which a multiple access DRAM memory device (e.g., OneDRAM®), an ASIC, and a flash memory are integrated. In the example of FIG. 2, the first package 200a has the POP structure formed by mounting a OneDRAM® 221 and a DRAM 223 on a package including a CPU 210.

As will be appreciated by those skilled in the art, the OneDRAM® 320 is a particular type of fusion memory including a fast, volatile memory (e.g., a DRAM) capable of enabling multiple access paths (e.g., by a CPU via one port and by an ASIC of a memory system via another port) to at least one shared memory area and at least one dedicated memory area. Hereafter, this type of memory—as best exemplified by the OneDRAM®—will be referred to as a “multiple access DRAM memory”. In the embodiments that follow, the OneDRAM® is adopted by way of example as the multiple access DRAM memory utilized in accordance with the inventive concept.

Still referring to FIG. 2, the second package 200b has an MCP structure formed by stacking a plurality of flash memories 241 to 244 and an ASIC 230 on a single substrate, respectively. The plurality of flash memories 241 to 244 may be formed of NAND flash memory and/or NOR flash memory. FIG. 2 shown an example in which there are four (4) flash memories, but the inventive concept is not limited in this manner.

The first package 200a and the second package 200b are spaced apart from each other on a substrate or board. In the case of this inventive concept, a package test is made with respect to the ASIC 230 and the flash memories 241 to 244 constituting the second package 200b where the OneDRAM® 221 is separated there from in the memory link architecture.

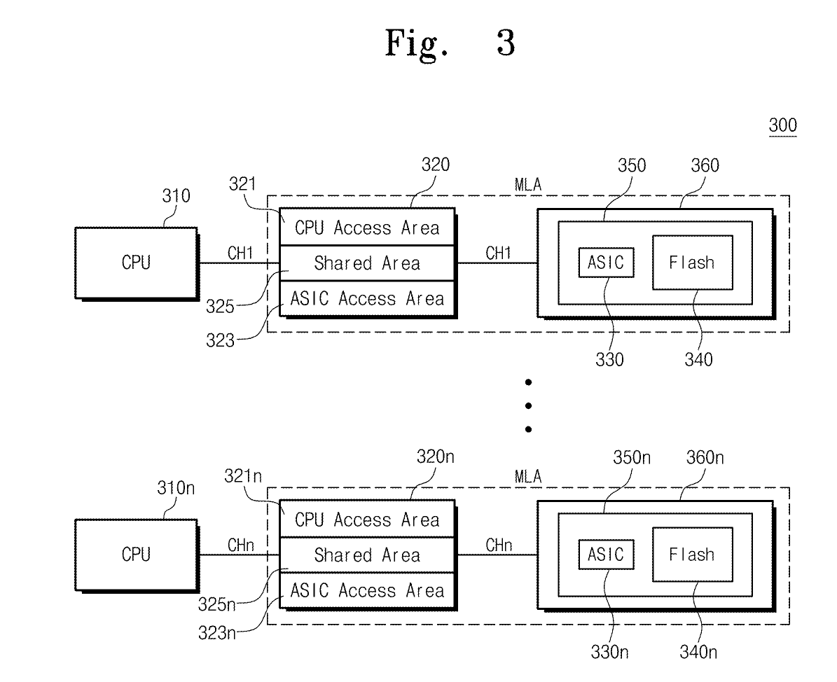

FIG. 3 is a diagram illustrating a multi-chip package test apparatus according to an embodiment of the inventive concept.

Referring to FIG. 3, a multi-chip package test apparatus 300 according to an embodiment of the inventive concept includes a plurality of CPUs 310 to 310n mounted on a test board, a plurality of OneDRAM® devices 320 to 320n, and a plurality of test sockets 360 to 360n.

During a package test, the CPUs 310 to 310n generate a test pattern using a test algorithm, and test functions on the ASICs 330 to 330n and the flash memories 340 to 340n mounted in the multi-chip packages 350 to 350n.

By using the OneDRAM® devices 320 to 320n, data is routed between processors within a mobile device via a single chip, so that a need for two memory buffers is removed. Further, a data processing speed between a communication processor and a media processor within the mobile device is improved by taking a dual port approach.

The OneDRAM® devices 320 to 320n include CPU access areas 321 to 321n only accessed by the CPUs 310 to 310n, ASIC access areas only accessed by the ASICs 330 to 330n, and shared areas exclusively accessed by respective ones of the CPUs 310 to 310n and the ASICs 330 to 330n.

During a package test, the OneDRAM® devices 320 to 320n may be disposed on channels CH1 to CHn formed between the CPUs 310 to 310n and the test sockets 360 to 360n, respectively.

Accordingly, each CPU tests functions on an ASIC and a flash memory as the memory link architecture (refer to a dotted box) via a respective OneDRAM®. For example, a CPU 310 tests functions on an ASIC 330 and a flash memory 340 via OneDRAM 320®, and a CPU 310n tests functions on an ASIC 330n and a flash memory 340n via OneDRAM® 320n.

The test sockets 360 to 360n may be configured such that the multi-chip packages 350 to 350n with an ASIC plus flash memory format are inserted therein.

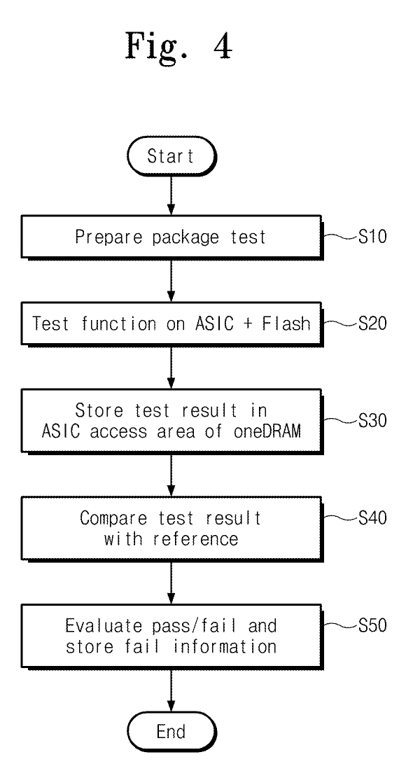

FIG. 4 is a flowchart illustrating a multi-chip package test method according to an embodiment of the inventive concept.

Below, an operation of a multi-chip package test apparatus according to an embodiment of the inventive concept will be more fully described with reference to accompanying drawings.

In step S10, to prepare a package test, multi-chip packages 350 to 350n with an ASIC plus flash memory format are inserted into test sockets 360 to 360n, respectively.

In step S20, CPUs 310 to 310n test functions on the multi-chip packages 350 to 350n using a test pattern. Herein, the test pattern may be generated using a test algorithm. Each multi-chip package is formed of an ASIC and a flash memory as illustrated in FIG. 3.

In an embodiment, the test algorithm may be stored in CPU access areas 321 to 321n of OneDRAM® devices 320 to 320n. That is, the CPU access areas 321 to 321n of the OneDRAM® devices 320 to 320n are used as memories of the CPUs 310 to 310n, so that test speed is increased because of the efficient use of memory during a package test.

In step S30, after functions of the multi-chip packages 350 to 350n are tested, test results are stored in ASIC access areas 323 to 323n of the OneDRAM® devices 320 to 320n, respectively.

In step S40, the CPUs 310 to 310n read the test results from the ASIC access areas 323 to 323n and judge whether a test is performed exactly or correct, based upon a comparison result between the test results and a reference value.

In the event that a test is made exactly, the multi-chip package test is judged to be passed. If a test is erroneous, the multi-chip package test is judged to be failed. In the latter case, failure information is stored to correct defects. The operation may be made in step S50.

Accordingly, a package test is made in parallel using a plurality of CPUs 310 to 310n corresponding to packages, respectively. This means that a package test is performed with rapid speed as compared with the case that a plurality of packages are tested using one CPU.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A multi-chip package test apparatus for testing a plurality of semiconductor packages including a plurality of flash memories and an application specific integrated circuit (ASIC) stacked on a single substrate, the multi-chip package test apparatus comprising:
a plurality of test sockets configured to receive the plurality of semiconductor packages, respectively;
a plurality of central processing units (CPUs) mounted on a test board and each configured to execute a package test of a respective one of the semiconductor packages received by the plurality of sockets; and
a plurality of multiple access dynamic random access memory (DRAM) device operatively interposed between the CPUs and test sockets, respectively, each of the multiple access DRAM devices configured with separate memory areas for access by a respective CPU and a respective ASIC of the semiconductor packages.

2. The multi-chip package test apparatus of claim 1, wherein each multiple access DRAM device comprises:
a CPU access area configured to be accessed only by a respective CPU;
an ASIC area configured to be accessed only by a respective ASIC; and
a shared area configured to be accessed exclusively by one of the respective CPU and the respective ASIC.

3. The multi-chip package test apparatus of claim 1, wherein each multiple access DRAM device is interposed in a channel formed between a respective CPU and a respective test socket.

4. The multi-chip package test apparatus of claim 1, wherein during the package test, each CPU generates a test pattern using a read test algorithm and tests a function on a respective ASIC and flash memory using the test pattern.

5. The multi-chip package test apparatus of claim 4, wherein the test algorithm is stored in a CPU access area of the multiple access DRAM devices, respectively.

6. The multi-chip package test apparatus of claim 1, wherein test results executed by the CPUs are stored in an ASIC access area of the multiple access DRAM devices, respectively.

7. A multi-chip package test method comprising:
inserting multi-chip packages each formed of an application specific integrated circuit (ASIC) and a flash memory into respective test sockets;
testing functions on the multi-chip packages inserted into the respective test sockets, the testing executed by respective central processing units (CPUs);
storing test results in an ASIC access areas of respective multiple access dynamic random access memory (DRAM) devices;
comparing the test results with a reference value, the comparing executed by the respective CPUs; and
evaluating and storing a pass/fail status of each of the multi-chip packages.

8. The multi-chip package test method of claim 7, wherein the CPUs test functions on the multi-chip packages using a test pattern generated by a test algorithm.

9. The multi-chip package test method of claim 8, wherein the test algorithm is stored in a CPU access area of the respective multiple access DRAM devices.

10. A multi-chip package test apparatus comprising:
a plurality of test sockets each configured to receive a package for testing;
a plurality of multiple access dynamic access memory (DRAM) devices respectively connected to the plurality of test sockets by at least one first channel; and
a plurality of central processing units (CPUs) respectively connected to the plurality of multiple access DRAM devices by at least one second channel.

11. The multi-chip package test apparatus of claim 10, wherein each multiple access DRAM device includes a CPU access memory area, an application specific integrated circuit (ASIC) access memory area, and a shared access memory area.

12. The multi-chip package test apparatus of claim 11, wherein a test algorithm is stored in the CPU access areas of the multiple access DRAM devices.

13. The multi-chip package test apparatus of claim 10, wherein a test result is stored in the ASIC access areas of the multiple access DRAM devices.
